(19) United States
(12) Patent Application Publication
(10) Pub. No.: US 2019/0088780 A1
(43) Pub. Date: Mar. 21, 2019

(54) DEMOS TRANSISTOR AND METHOD OF MANUFACTURING THE SAME

(71) Applicant: DB HITEK CO., LTD., Seoul (KR)

(72) Inventors: Kee Joon CHOI, Bucheon-si (KR); Bon Sug KOO, Bucheon-si (KR); Bum Seok KIM, Seoul (KR); Mi Hye JUN, Guri-si (KR); Hae Taek KIM, Bucheon-si (KR); Duk Joo WOO, Bucheon-si (KR)

(21) Appl. No.: 16/135,459

(22) Filed: Sep. 19, 2018

(30) Foreign Application Priority Data
Sep. 20, 2017 (KR) 10-2017-0120910

(51) Int. Cl. H01L 29/78; H01L 29/66; H01L 29/08

(52) U.S. Cl. CPC H01L 29/7835; H01L 29/7816; H01L 29/66659; H01L 29/0886; H01L 29/66681

(57) ABSTRACT

A DEMOS transistor includes a semiconductor substrate defining a field region and an active region, a gate pattern disposed on the semiconductor substrate, the gate pattern being positioned over both the active region and the field region, drift regions disposed in the active region and positioned adjacent to both sides of the gate pattern, high concentration ion regions disposed in the drift regions, and being spaced apart from the gate pattern, and a silicide blocking layer having a exposure hole exposing one of an upper surface of the gate pattern and the high concentration ion regions, the silicide blocking layer having a ring shape to at least partially surround one of the upper surface of the gate pattern and the high concentration ion regions.

### CROSS-REFERENCE TO RELATED APPLICATION

This application claims priority to Korean Patent Application No. 10-2017-0120910, filed on Sep. 20, 2017 and all the benefits accruing therefrom under 35 U.S.C. § 119, the contents of which are incorporated by reference in their entirety.

### TECHNICAL FIELD

The present disclosure relates to a DEMOS transistor and a method of manufacturing the same and more particularly, to a drain extended metal oxide semiconductor (DEMOS) transistor and a method of manufacturing the DEMOS transistor.

### BACKGROUND

N or P channeled drain extended metal oxide semiconductor transistor devices have been used for high power switching applications. For example, the drain extended metal oxide semiconductor transistor device includes lateral double diffused MOS (LDMOS) devices and RESURF (Reduced Surface Field) transistors.

In particular, a drain extended metal oxide field effect transistor (hereinafter referred to as a DEMOS transistor) has been developed where a drain region is extended to increase a breakdown voltage (BV) value of a transistor device.

The DEMOS transistor may have the capability to withstand a high blocking voltage without having a relatively low drain-source on-state resistance (Rdson) and a voltage yield failure.

Generally, the breakdown voltage (BV) is measured as the drain-source breakdown voltage (BVdss) at which the gate and the source electrically short together. In designing DEMOS transistors, it has been discovered that the breakdown voltage (BVdss) and the drain-source on-state resistance (Rdson) have a trade-off relationship.

In addition to the above excellent performance, the fabrication process for fabricating the DEMOS transistor device is relatively easy to integrate into the CMOS process flow, so that the DEMOS transistor may be easily adapted to devices including a single integrated circuit (IC) together with a logic circuitry, a low power analog circuitry or other circuitry.

Hereinafter, N typed DEMOS transistors will be described with reference to the accompanying drawings.

FIG. 1 is a plan view illustrating a conventional MOS transistor.

Referring to FIG. 1, a conventional drain-extended MOS transistor includes a substrate, a gate, and an extended N+junction region 16A and 16B. That is, the N+junction regions 16A and 16B are extended from the gate to be used as a high voltage device. Here, an n-type MOS transistor will be described in more detail below with reference to the embodiment of FIG. 2.

In the well 10 of the semiconductor substrate, a gate is formed in the active region defined between the device isolation layers. A gate insulating layer pattern is formed between the gate and the substrate. Thus, a gate pattern including the gate and gate insulating layer pattern is provided. Also, a silicide layer 24 is formed on the N+junctions 18A and 18B and on the gate. Also, silicide layers 24 are formed on the N+junctions 18A and 18B and on the gate. Contacts 26A and 26B are formed on one of the silicide layers 24.

Silicide blocking (SAB) layer 22A, 22B are also formed in the drift regions 16A, 16B and extend from the gate to the N+junctions 18A, 18B. Therefore, a high voltage drift junction breakdown voltage may be secured. Further, each of the silicide blocking layers may have a bar shape or a stripe shape.

However, in order to pattern the silicide blocking layers 22A and 22B, a distance from the gate to the N+junctions 18A and 18B needs to be secured over a certain dimension. Particularly, in the case where the width of each of the silicide blocking layers in the drift regions 16A and 16B is less than a critical dimension (CD), the actual layout may not be satisfied due to a lack of the photo margin in an exposure process. Therefore, it may be difficult to form the silicide blocking layers having the same shape as intended.

Particularly, when an exposure process for patterning the silicide blocking layers 22A and 22B is insufficiently performed, the reaction in the subsequent silicide process is suppressed, so that the contact resistance of the MOS transistor device may be increased. On the other hand, when the exposure process is performed excessively, an undesirable silicide reaction occurs at an edge portion of the active region, so that a defective leakage current may occur in the MOSFET transistor. Furthermore, as the width of the active region decreases, it becomes difficult to perform the patterning process for forming the silicide blocking layers.

### SUMMARY

The example embodiments of the present invention provide a DEMOS transistor capable of securing a process margin in a photoresist exposure process for patterning a silicide blocking layer such that a failure of a silicidation process does not result in the aforementioned failure modes for the overall MOSFET.

The example embodiments of the present invention provide a method of manufacturing a DEMOS transistor capable of securing a process margin in a photoresist exposure process for patterning a silicide blocking layer such that a failure of a silicidation process may be suppressed.

According to an example embodiment of the present invention, a DEMOS transistor includes a semiconductor substrate defining a field region and an active region, a gate pattern disposed on the semiconductor substrate, the gate pattern arranged over both the active region and the field region, a plurality of drift regions, wherein each of the drift regions is disposed in the active region, and wherein both sides of the gate pattern are adjacent to at least one of the plurality of drift regions, a plurality of high concentration ion regions disposed in the drift regions and spaced apart from the gate pattern, and a silicide blocking layer having a exposure hole exposing one of an upper surface of the gate pattern and the high concentration ion regions, the silicide blocking layer having a ring shape to at least partially surround one of the upper surface of the gate pattern and the high concentration ion regions.

In an example embodiment, the active region may have a stripe shape of extending along a first direction, and the silicide blocking layer may partially cover the field region.

Here, the silicide blocking layer may surround the gate pattern.

Further, the exposure hole may extend along a second direction perpendicular to the first direction to be positioned over a portion of the field region.

Here, the silicide blocking layer may surround each of the high concentration ion regions, and the exposure hole may extend along a second direction perpendicular to the first direction to be positioned over a portion of the field region.

According to an example embodiment of the present invention, a drain extended MOS transistor is manufactured by the following steps. A gate pattern is formed on a semiconductor substrate defined by a field region and an active region, wherein the gate pattern is formed on the active region. Then, an ion implantation process is performed using the gate pattern as a mask to form drift regions in the active region that are adjacent to both sides of the gate pattern. High concentration ion regions are formed in each of the drift regions, wherein the high concentration ion regions are spaced apart from the gate pattern. Then, a silicide blocking layer having a ring shape is formed so as to at least partially surround one of an upper surface of the gate pattern and he high concentration ion regions, the silicide blocking layer having an exposure hole to expose one of the upper surface of the gate pattern and the high concentration ion regions.

In an example embodiment, the active region may have a stripe shape of extending along a first direction, and the gate pattern may be formed to partially cover the field region.

In an example embodiment, the silicide blocking layer may surround the gate pattern.

Here, the exposure hole may extend along a second direction perpendicular to the first direction to be positioned over a portion of the field region.

Further, the silicide blocking layer may surround each of the high concentration ion regions, and the exposure hole may extend along a second direction perpendicular to the first direction to be positioned over a portion of the field region.

In an example embodiment, a silicide layer may be further formed on exposed portions of the gate pattern and the upper regions of the high-concentration ion regions, which are exposed by the exposure hole, and via contacts may be further formed on the silicide layer to be electrically connected to the silicide layer.

According to the DEMOS transistor and the method of manufacturing the same of the present invention, unlike a typical middle-voltage transistor having a structure in which it may be difficult to form a silicide blocking layer, the silicide blocking layer may be formed in a region between a gate pattern and a contact, that is, on the source/drain region of the high concentration. Thus, the break down voltage may be increased and the gate length of the transistor can be reduced. Furthermore, the pattern of the silicide blocking layer may be connected to each other as if supporting each other, so that the pattern collapse phenomenon against the silicide blocking layer may be prevented and a process margin of the exposure process may be ensured.

The above summary is not intended to describe each illustrated embodiment or every implementation of the subject matter hereof. The figures and the detailed description that follow more particularly exemplify various embodiments.

### BRIEF DESCRIPTION OF THE DRAWINGS

Subject matter hereof may be more completely understood in consideration of the following detailed description of various embodiments in connection with the accompanying figures, in which:

FIG. 1 is a plan view illustrating a conventional MOS transistor;

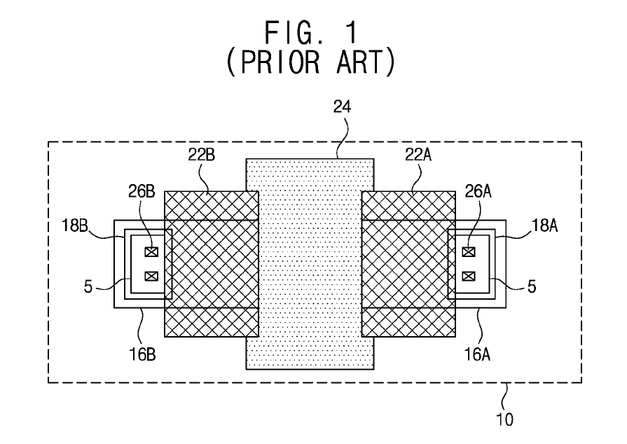

FIG. 2 is a plan view illustrating a DEMOS transistor in accordance with an example embodiment of the present invention;

FIGS. 3 to 6 are cross sectional views illustrating a method of manufacturing a DEMOS transistor in accordance with an example embodiment of the present invention; and

FIG. 7 is a plan view illustrating a DEMOS transistor in accordance with an example embodiment of the present invention.

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION OF THE DRAWINGS

Hereinafter, specific embodiments will be described in more detail with reference to the accompanying drawings. The present invention may, however, be embodied in different forms and should not be construed as limited to the embodiments set forth herein.

As an explicit definition used in this application, when a layer, a film, a region or a plate is referred to as being ‘on’ another one, it can be directly on the other one, or one or more intervening layers, films, regions or plates may also be present. Unlike this, it will also be understood that when a layer, a film, a region or a plate is referred to as being ‘directly on’ another one, it is directly on the other one, and one or more intervening layers, films, regions or plates do not exist. Also, though terms like a first, a second, and a third are used to describe various components, compositions, regions and layers in various embodiments of the present invention are not limited to these terms.

Furthermore, and solely for convenience of description, elements may be referred to as “above” or “below” one another. It will be understood that such description refers to the orientation shown in the Figure being described, and that in various uses and alternative embodiments these elements could be rotated or transposed in alternative arrangements and configurations.

In the following description, the technical terms are used only for explaining specific embodiments while not limiting the scope of the present invention. Unless otherwise defined herein, all the terms used herein, which include technical or scientific terms, may have the same meaning that is generally understood by those skilled in the art.

The depicted embodiments are described with reference to schematic diagrams of some embodiments of the present invention. Accordingly, changes in the shapes of the diagrams, for example, changes in manufacturing techniques and/or allowable errors, are sufficiently expected. Accordingly, embodiments of the present invention are not described as being limited to specific shapes of areas described with diagrams and include deviations in the shapes and also the areas described with drawings are entirely schematic and their shapes do not represent accurate shapes and also do not limit the scope of the present invention.

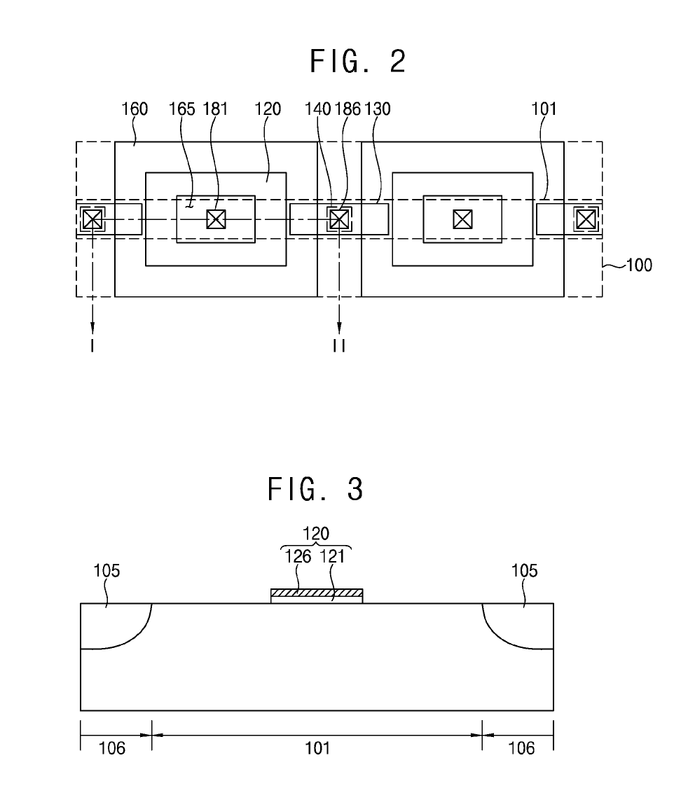

FIG. 2 is a plan view illustrating a DEMOS transistor in accordance with an example embodiment of the present invention.

Referring to FIG. 2, a DEMOS transistor in accordance with an example embodiment of the present invention includes a semiconductor substrate 100, a gate pattern 120, drift regions 130, high concentration ion regions 140, and a silicide blocking layer 160.

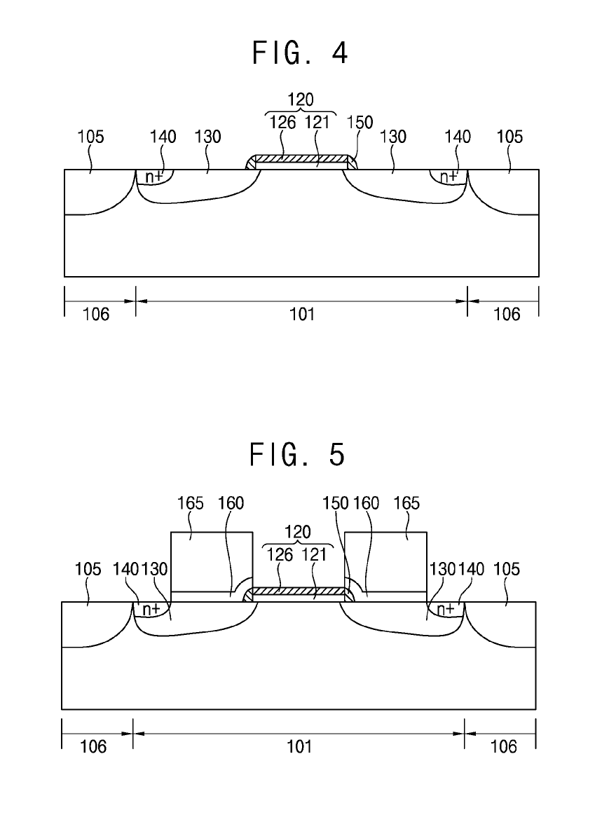

The semiconductor substrate 100 is divided into a field region 106 and an active region 101 (see FIG. 3). The semiconductor substrate 100 has a shallow trench isolation layer (STI layer) 105 (see FIG. 3) disposed at an upper surface portion of the semiconductor substrate 100 to separate the active region 101 from the field region 106. Alternatively, a field oxide layer (not shown) may be divided into the field region and the active region. The field oxide layer may be formed at the surface portion of the semiconductor substrate 100. That is, one region where the field oxide layer is formed may correspond to the field region, whereas the other region where the field oxide layer is not formed may correspond to the active region.

As shown in FIG. 2, the active region 101 may have a stripe shape extending in a first direction.

A well (not shown) is formed in the semiconductor substrate in the active region 101. A gate pattern 120 is formed in the active region of the semiconductor substrate. Further, the active region may extend to cross the gate pattern 120.

The gate pattern 120 may include a polysilicon gate 126 (see FIG. 3) and a gate insulating layer 121 (see FIG. 3). As shown in FIG. 2, the gate pattern 120 is formed to intersect with the active region 101. In addition, the gate pattern 120 is formed over the active region 101 and over the field region 106.

The drift regions 130 are formed in the active region 101. Each of the drift regions 130 is formed adjacent to both sides of the gate pattern 120 to be interposed between a plurality of gate patterns 120 such that they are adjacent to each other. Each of the drift regions 130 is formed to surround the source and drain regions. That is, the source and drain regions may correspond to regions where source and drain are defined in the active region 101 and adjacent to both sides of the gate pattern 120.

The drift regions 130 may extend the drain. As a result, the drain extended MOS transistor has an increased breakdown voltage and may be applied to a high voltage power device.

The high-concentration ion regions 140 are formed in each of the drift regions 130, respectively. Further, the high-concentration ion regions 140 are spaced apart from the gate pattern 120. The high-concentration ion regions 140 may correspond to source/drain.

The silicide blocking (SAB) layer 160 covers an edge portion of the gate pattern 120 to surround the gate pattern 120. The silicide blocking layer 160 partially covers the drift regions 130 as well.

For example, the silicide blocking layer 160 has a ring shape. That is, the silicide blocking layer 160 has an exposure hole 165 to expose a silicide formation region. Here, the silicide formation region may correspond to a portion of an upper surface of the gate pattern 120.

The silicide blocking layer 160 may be disposed over the active region 101 and the field region 106. That is, one portion of the silicide blocking layer 160 may be formed on the field region 106 and the other portion of the silicide blocking layer 160 may be formed on the active region 101.

For example, the silicide blocking layer 160 has a polygonal ring shape such as a rectangular ring shape.

Alternatively, the silicide blocking layer 160 may have a circular ring shape. Thus, one portion of the silicide blocking layer 160 may be disposed on the field region 106 to define a round portion having a rounded shape. As the silicide blocking layer 160 has a rounded ring shape, a leakage current which may occur adjacent to a boundary area between the active region 101 and the field region 106 due to an electric field concentration may be suppressed.

The silicide blocking layer 160 may be formed through the following process.

First, a layer of silicide blocking material layer (not shown) is formed on a semiconductor substrate. Then, the silicide blocking material layer is patterned to form the silicide blocking layer to expose the silicide forming region. In detail, a photoresist pattern exposing the silicide layer forming region is formed on the silicide blocking material layer in order to utilize the photoresist pattern as an etch mask for patterning the silicide blocking layer material layer. Then, an etch process is performed against the silicide blocking material layer using the photoresist pattern as an etch mask to form the silicide blocking layer. The etch process may include an exposure process and a development process against the silicide blocking material layer.

While the process of forming the silicide blocking layer 160 is performed, the silicide blocking layer 160 including the exposure hole 165 for exposing the gate pattern 120 is formed over the field region 106 as well as the active region 101. Thus, the process margin of the exposure process can be increased. Therefore, since the exposure process can be performed relatively satisfactorily, defects such as leakage current which may occur due to underexposure may be suppressed.

According to the conventional art, the silicide blocking layer has a ring shape so that an exposure hole of the silicide blocking layer exposes an upper surface of the high concentration ion regions which may correspond to the silicide forming region. Thus, the narrower the width of the active region 101, the narrower the width of the high concentration ion region. Thus, a patterning process against the silicide blocking material layer for transforming the silicide blocking material layer into the silicide blocking layer which has the exposure hole for exposing the high-concentration ion region 140 may be difficult.

On the other hand, according to some embodiments of the present invention, the gate pattern 120 may occupy a relatively larger area than the high concentration ion regions 140. Accordingly, when the exposure hole 165 formed in the silicide blocking layer 160 exposes the gate pattern 120, a patterning process for forming the silicide blocking layer 160 having the exposure hole 165 may secure a large process margin.

Although not shown in FIG. 2, the silicide blocking layer 160 may be formed in a region where the silicide blocking layer 160 is not covered to expose among an entire area of an upper surface of the gate pattern 120 and the high concentration ion regions 140.

The transistor shown in FIG. 2 may be a high voltage (HV) drain-extended (DE) NMOS transistor or a drain extended (DE) PMOS transistor. If the transistor shown in FIG. 2 is a DE-NMOS, the well may be of the P type conductivity, and the drift regions 130 and the high concentration ion regions 140 may be of N type conductivity. Conversely, when the transistor shown in FIG. 2 is a DE-PMOS, the well may be of N type conductivity, the drift regions 130 and the high concentration ion regions 140 may be of P type conductive.

FIGS. 3 to 6 are cross sectional views illustrating a method of manufacturing a DEMOS transistor in accordance with an example embodiment of the present invention.

Referring to FIG. 3, according to an example embodiment of the present invention, first a well is formed in a semiconductor substrate (not shown) defined by a field region 106 and an active region 101. Here, a shallow trench isolation (STI) layer 105 may be formed at an upper surface of the substrate, which defines the field region 106.

Then, the gate pattern 120 is formed on the active region 101. For example, an insulating layer (not shown) such as an oxide layer and a polysilicon layer (not shown) are sequentially stacked on the active region 101 and then photolithography and etching processes are performed to form the gate pattern 120 including the gate insulating layer 121 and the gate 126 stacked on the semiconductor substrate.

Referring to FIG. 4, an ion implantation process using the gate pattern 120 as an ion implantation mask is performed to form drift regions 130 in the active region 1012. That is, in the active region 101 at both sides of the gate pattern 120, the drift regions 130 are formed to surround the source and drain regions which are to be formed as high concentration ion regions in a subsequent process. Then, a spacer 150 may be formed on a side wall of the gate pattern 120.

Referring to FIG. 5, high concentration ion regions 140 are formed in the drift regions 130 and the high concentration ion regions 140 is spaced apart from the gate pattern 120 at a predetermined distance. In particular, in order to form the high concentration ion regions 140, an ion implantation mask (not shown) for exposing the high concentration ion regions 140 is formed on the semiconductor substrate including the gate pattern 120, and then impurity ions is implanted at a high concentration using the ion implantation mask to form the high concentration ion regions 140. After forming the high-concentration ion regions 140, the ion-implantation mask is removed from the semiconductor substrate.

Thus, the drift regions 130 and the high concentration ion regions 140 are formed to form a junction of the high-voltage transistor.

Referring to FIG. 5, a silicide blocking layer 160 is formed on the drift region 130 between the gate pattern 120 and the high concentration ion region 140. The silicide blocking layer 160 may serve to prevent silicide in the subsequent silicide process from forming at a portion between the gate pattern 120 and the high concentration ion region 140.

In addition, the silicide blocking layer 160 has a ring shape. That is, the silicide blocking layer 160 is formed with an exposure hole 165 for exposing the silicide formation region. Here, the silicide formation region may correspond to a portion of the upper surface of the gate pattern 120. The silicide blocking layer 160 may be formed as a whole over the active region 101 and the field region 106. That is, a portion of the silicide blocking layer 160 may be disposed to partially cover the field region.

For example, the silicide blocking layer 160 may have a polygonal ring shape such as a rectangular ring shape.

Alternatively, the silicide blocking layer 160 may have a circular ring shape. A portion of the silicide blocking layer 160 formed on the field region 106 may correspond to a round portion having a rounded shape. Since the silicide blocking layer 160 has a rounded ring shape, the leakage current which may occur due to the electric field concentration may be suppressed.

Referring again to FIG. 5, a silicide blocking material layer (not shown) is formed on the semiconductor substrate. Next, the silicide blocking material layer is patterned to expose the silicide forming regions. In order to pattern the silicide blocking layer material layer, a photoresist pattern 165 is formed on the silicide blocking material layer. The silicide blocking material layer is patterned using the photoresist pattern 165 as a mask to expose the silicide layer forming region such that the silicide blocking layer 160 is formed.

While the process of forming the silicide blocking layer 160 is performed, the silicide blocking layer 160 including the exposure hole 165 for exposing the gate pattern 120 is formed over the field region 106 as well as the active region 101. Thus, the process margin of the exposure process can be increased. Therefore, since the exposure process can be performed relatively sufficiently, defects such as leakage current which may occur due to underexposure may be suppressed.

According to the conventional art, the silicide blocking layer has a ring shape so that an exposure hole of the silicide blocking layer exposes an upper surface of the high concentration ion regions which may correspond to the silicide forming region. Thus, the narrower the width of the active region 101, the narrower the width of the high concentration ion region. Thus, a patterning process against the silicide blocking material layer for transforming the silicide blocking material layer into the silicide blocking layer which has the exposure hole for exposing the high-concentration ion region 140 may be difficult.

On the other hand, according to some embodiments of the present invention, the gate pattern 120 may occupy a relatively larger area than the high concentration ion regions 140. Accordingly, when the exposure hole 165 formed in the silicide blocking layer 160 exposes the gate pattern 120, a patterning process for forming the silicide blocking layer 160 having the exposure hole 165 may secure a large process margin.

Referring to FIG. 6, silicide layers 171A, 171B are formed on the exposed portions of the gate pattern 120 and the upper regions of the high-concentration ion regions 140, which are exposed by the exposure hole and are not covered by the silicide blocking layer 160.

Then, an interlayer insulating layer (not shown) is formed on an entire upper surface of the semiconductor substrate including the silicide layers 171A and 171B, and a via hole (not shown) for exposing each of the silicide layers 171A and 171B is formed through the interlayer insulating layer, and then a metal such as tungsten is buried in the via hole to form via contacts 181 and 186.

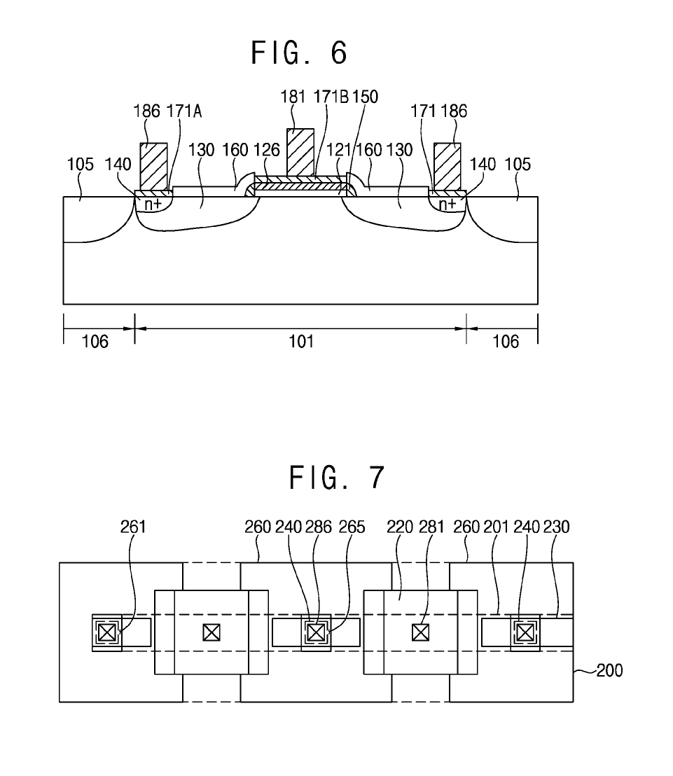

FIG. 7 is a plan view illustrating a DEMOS transistor in accordance with an example embodiment of the present invention.

Referring to FIG. 7, a drain extended (DE) MOS transistor according to another embodiment of the present invention includes a semiconductor substrate 200, a gate pattern 220, drift regions 230, high concentration ion regions 240, and a silicide blocking layer 260.

Hereinafter, differences between the DEMOS transistor in FIG. 7 and the DEMOS transistor shown in FIG. 3 will be mainly described.

The silicide blocking layer 260 may be provided to surround each of the drift regions 230. Further, the silicide blocking layer 260 may be provided to surround each of the high concentration ion regions 240. The silicide blocking layer 260 may have a ring shape. An exposure hole 265 is formed at a center portion of the silicide blocking layer 260 to expose a portion of each of upper surfaces of the high concentration ion regions 240.

As not shown in FIG. 7, the silicide layer may be formed in the region not covered by the silicide blocking layer 260. Thus, the silicide layer may be formed on both an upper surface of the gate pattern 220 and exposed portions of the drift regions 230.

Although the DEMOS transistor and the method of manufacturing the DEMOS transistor have been described with reference to the specific embodiments, they are not limited thereto. Therefore, it will be readily understood by those skilled in the art that various modifications and changes can be made thereto without departing from the spirit and scope of the appended claims.

Various embodiments of systems, devices, and methods have been described herein. These embodiments are given only by way of example and are not intended to limit the scope of the claimed inventions. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the claimed inventions.

Persons of ordinary skill in the relevant arts will recognize that the subject matter hereof may comprise fewer features than illustrated in any individual embodiment described above. The embodiments described herein are not meant to be an exhaustive presentation of the ways in which the various features of the subject matter hereof may be combined. Accordingly, the embodiments are not mutually exclusive combinations of features; rather, the various embodiments can comprise a combination of different individual features selected from different individual embodiments, as understood by persons of ordinary skill in the art. Moreover, elements described with respect to one embodiment can be implemented in other embodiments even when not described in such embodiments unless otherwise noted.

Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims, it is expressly intended that the provisions of 35 U.S.C. § 112(f) are not to be invoked unless the specific terms “means for” or “step for” are recited in a claim.

1. A drain extended MOS transistor comprising:
a semiconductor substrate defining a field region and an active region;
a gate pattern disposed on the semiconductor substrate, the gate pattern arranged over both the active region and the field region;
a plurality of drift regions, wherein each of the drift regions is disposed in the active region, and wherein both sides of the gate pattern are adjacent to at least one of the plurality of drift regions;
a plurality of high concentration ion regions disposed in the drift regions and spaced apart from the gate pattern; and
a silicide blocking layer having a exposure hole exposing one of an upper surface of the gate pattern and the high concentration ion regions, the silicide blocking layer having a ring shape to at least partially surround one of the upper surface of the gate pattern and the high concentration ion regions.

2. The drain extended MOS transistor of claim 1, wherein the active region has a stripe shape of extending along a first direction, and the silicide blocking layer partially covers the field region.

3. The drain extended MOS transistor of claim 2, wherein the silicide blocking layer at least partially surrounds the gate pattern.

4. The drain extended MOS transistor of claim 3, wherein the exposure hole extends along a second direction perpendicular to the first direction and is positioned over a portion of the field region.

5. The drain extended MOS transistor of claim 2, wherein the silicide blocking layer surrounds each of the high concentration ion regions, and the exposure hole extends along a second direction perpendicular to the first direction to be positioned over a portion of the field region.

6. A method of manufacturing a drain extended MOS transistor, the method comprising:
forming a gate pattern on a semiconductor substrate defined by a field region and an active region, wherein the gate pattern is formed on the active region;
performing an ion implantation process using the gate pattern as a mask to form drift regions in the active region that are adjacent to both sides of the gate pattern;
forming high concentration ion regions in each of the drift regions, wherein the high concentration ion regions are spaced apart from the gate pattern; and
forming a silicide blocking layer having a ring shape so as to at least partially surround one of an upper surface of the gate pattern and he high concentration ion regions, the silicide blocking layer having an exposure hole to expose one of the upper surface of the gate pattern and the high concentration ion regions.

7. The method of claim 6, wherein the active region has a stripe shape of extending along a first direction, and the gate pattern is formed to partially cover the field region.

8. The method of claim 7, wherein the silicide blocking layer at least partially surrounds the gate pattern.

9. The method of claim 8, wherein the exposure hole extends along a second direction perpendicular to the first direction to be positioned over a portion of the field region.

10. The method of claim 8, wherein the silicide blocking layer surrounds each of the high concentration ion regions, and the exposure hole extends along a second direction perpendicular to the first direction to be positioned over a portion of the field region.

11. The method of claim 6, further comprising:
forming a silicide layer on exposed portions of the gate pattern and the upper regions of the high-concentration ion regions, which are exposed by the exposure hole; and
forming via contacts on the silicide layer to be electrically connected to the silicide layer.
